(19) United States
(12) Patent Application Publication
(10) Pub. No.: US 2026/0190255 A1
(43) Pub. Date: Jul. 2, 2026

(54) SYSTEM AND METHOD FOR SHELF LATCHING

(71) Applicant: Advanced Energy Industries, Inc., Denver, CO (US)

(72) Inventors: Jerome G. Antaran, Paranaque City (PH); Ryan Roxas, Taguig City (PH); Carl Aaron Antonio Lagazo, Quezon city (PH)

(21) Appl. No.: 19/005,292

(22) Filed: Dec. 30, 2024

(51) Int. Cl. H05K 5/02

(52) U.S. Cl. CPC H05K 5/0221; H05K 5/023

(57) ABSTRACT

A latch assembly comprises a latch having a first protrusion extending from a first end of the latch, a lever having a first portion adjacent to a first protrusion opening, and a bracket configured to engage the lever to confine a movement of the lever along a sliding axis. The first protrusion opening is configured to allow a portion of the first protrusion to extend therethrough, a sliding movement of the lever along the sliding axis in a first direction causes a greater amount of the first protrusion to be within the first protrusion opening, and a sliding movement of the lever along the sliding axis in a second direction causes a lesser amount of the first protrusion to be within the first protrusion opening.

### TECHNICAL FIELD

Aspects of the disclosure relate to output power distribution and, more particularly, to latching methods for shelf systems in a rack mount system.

### BACKGROUND

It is well known to use equipment racks for mounting and supporting multiple equipment modules. For example, racks are widely used in modern data centers, ISP facilities and corporate server rooms for mounting and supporting various equipment modules, including computing, telecommunication, audio, and/or video equipment. Generally, the equipment rack is connected to an AC or DC power source, and the equipment rack converts the input power (e.g., AC or DC) to required DC output power for the equipment installed in the rack via power supply units (PSUs).

In general, the rack mountable equipment or product (e.g., network switch, server, data storage system, etc.) is designed without an integral power supply. Instead, the product is powered by a central power distribution system (PDS) of the rack. The product is electrically connected to the PDS via bus bars (e.g., a 48V or 12V DC bus bar and a ground bus bar) located along the rear of the rack. The product may be electrically connected to the rack bus bars in order to input the bus bar voltage to power the product.

A power shelf within the rack mount system can include a number of power supplies to convert AC power into DC power for the PDS. The power requirements for a rack setup can vary according to the voltage load requirements of the equipment/components installed in the rack.

Shelf systems have been implemented to hold an array of such electronic modules; however, space is limited within each shelf as the density of circuit(s) and parts within the electronic modules increase. Further, structures are needed to ensure the power shelves are fixed to the shelf and will not eject when undergoing shock or vibrations.

### SUMMARY

In accordance with one aspect of the present disclosure, a latch assembly comprises an inner latch having a first protrusion formed in a proximal end of the inner latch, a lever having a first protrusion opening formed in a distal end of the lever, and a bracket configured to engage the lever to confine a movement of the lever along a sliding axis. The first protrusion opening is configured to allow a portion of the first protrusion to extend therethrough, a sliding movement of the lever along the sliding axis in a first direction causes a greater amount of the first protrusion to be within the first protrusion opening, and a sliding movement of the lever along the sliding axis in a second direction causes a lesser amount of the first protrusion to be within the first protrusion opening.

In accordance with another aspect of the present disclosure, a latching component comprises a chassis comprising a chassis wall and a latch member having a proximal portion thereof affixed to the chassis wall and comprising a distal end and a first latch tooth formed at the distal end. The latching component also comprises a bracket fixedly attached to the chassis wall and a lever comprising a distal end positioned between the distal end of the latch member and the chassis wall and a bracket portion positioned between the bracket and the chassis wall. The distal end of the lever has a first latch tooth opening formed therein, the lever is configured to slide in a first direction to allow a greater portion of the first latch tooth to be positioned within the first latch tooth opening, and the lever is configured to slide in a second direction opposite the first direction to allow a lesser portion of the first latch tooth to be positioned within the first latch tooth opening.

In accordance with yet another aspect of the present disclosure, a method comprises forming a pair of latching teeth in a distal end of a latch, attaching a proximal end of the latch to a chassis wall, forming a pair of latch teeth openings in a distal end of a lever, coupling the lever with the distal end of the latch, and attaching a bracket to the chassis wall and about a portion of the lever. The bracket is configured to allow sliding movement of the lever with respect to the latch. In response to sliding movement of the lever in a first direction, the pair of latching teeth is caused to be moved in an insertion direction within the latch teeth openings. In response to sliding movement of the lever in a second direction, the pair of latching teeth is caused to be moved in a withdrawal direction within the latch teeth openings.

### BRIEF DESCRIPTION OF THE DRAWINGS

The drawings illustrate embodiments presently contemplated for carrying out the invention.

In the drawings:

FIG. 1 illustrates a block diagram of an equipment rack according to one or more embodiments.

FIG. 2 illustrates the power shelf of FIG. 1 latched within a portion of the equipment rack enclosure of FIG. 1 according to one or more embodiments.

FIG. 3 illustrates an exploded view of the latch assembly of FIG. 2 according to one or more embodiments.

FIG. 4 illustrates an isometric view of the latch assembly of FIG. 2 in a latching state according to one or more embodiments.

FIG. 5 illustrates an isometric view of the latch assembly of FIG. 2 in an unlatching state according to one or more embodiments.

FIG. 6 illustrates a plan view of the latch assembly of FIG. 4 in the latching state according to one or more embodiments.

FIG. 7 illustrates a plan view of the latch assembly of FIG. 5 in the unlatching state according to one or more embodiments.

FIG. 8 illustrates a cutaway view of a portion of the latch assembly of FIG. 4 according to one or more embodiments.

FIG. 9 illustrates a cutaway view of a portion of the latch assembly of FIG. 4 according to one or more embodiments.

FIG. 10 illustrates an isometric view of an alternative latch assembly in a latching state according to one or more embodiments.

FIG. 11 illustrates an isometric view of the latch assembly of FIG. 10 in an unlatching state according to one or more embodiments.

While the present disclosure is susceptible to various modifications and alternative forms, specific embodiments thereof have been shown by way of example in the drawings and are herein described in detail. It should be understood, however, that the description herein of specific embodiments is not intended to limit the present disclosure to the particular forms disclosed, but on the contrary, the intention is to cover all modifications, equivalents, and alternatives falling within the spirit and scope of the present disclosure. Note that corresponding reference numerals indicate corresponding parts throughout the several views of the drawings.

### DETAILED DESCRIPTION

Examples of the present disclosure will now be described more fully with reference to the accompanying drawings. The following description is merely exemplary in nature and is not intended to limit the present disclosure, application, or uses.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention, which is defined by the claims.

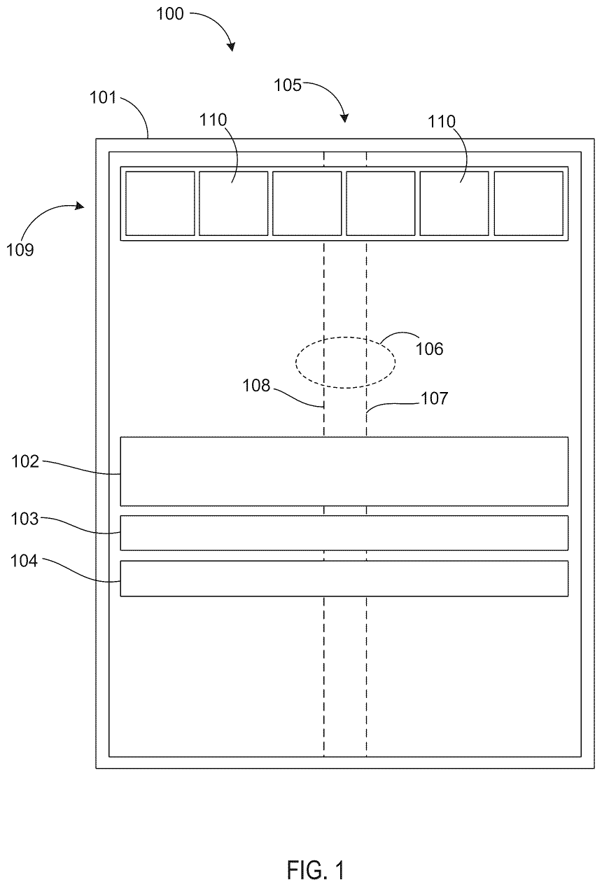

FIG. 1 illustrates a block diagram of an equipment rack 100 according to an embodiment. Equipment rack 100 includes an enclosure 101 capable of housing and supporting multiple pieces of equipment 102, 103, 104 such as computing, telecommunication, audio, and/or video equipment and the like. The enclosure 101 may be configured to accept specific sizes of equipment in designated locations or may be configured to allow the installation of equipment at any of various vertical positions to accommodate multiple equipment layouts.

The energy to power the equipment 102, 103, 104 is provided by a central power distribution system (PDS) 105 of the rack. PDS 105 includes a rack bus system 106 having two or more power rails 107, 108 generally located at the rear of the enclosure 101 for providing power into the rear of each piece of equipment 102, 103, 104. In one embodiment, the rack bus system 106 can be a DC power system providing a neutral power rail 107 and a voltage rail 108 having a positive or negative voltage with respect to the neutral power rail 107.

The PDS 105 receives power from one or more power shelves 109 having a plurality of power supply units (PSUs) 110 configured to receive AC or DC power and convert the received power to a DC output power for powering the equipment 102, 103, 104. As illustrated in FIG. 1, the plurality of PSUs 110 may be arranged in a multi-column format. In other embodiments, the plurality of PSUs 110 may be arranged in a multi-column, multi-row format within each power shelf 109. As described herein, the voltage outputs of the plurality of PSUs 110 are coupled together and tied to the PDS 105 to provide a desired power to the PDS 105. For example, the PDS 105 may be designed to receive a desired power from the one or more power shelves 109 (e.g., 15 kW power) with a target DC system voltage (e.g., 12V DC). Accordingly, a number of PSUs 110, each providing a portion of the total desired power, are installed in the power shelf 109 and coupled together to provide the desired power. The number of PSUs 110 to be installed can depend on the output capacity of each PSU 110. In a scenario where each PSU 110 is designed to output 1,250 A of current at 12V DC, a total of twelve PSUs 110, as illustrated, are installed in the power shelf 109 to yield a total output power of 15 kW. However, the number of PSUs 110 installed in the power shelf 109 may be more or fewer than that illustrated based on the capability of the PSUs 110 to provide a different power output. Due to a width constraint of the enclosure 101, the PSUs 110 may not be able to fit along a single row of the equipment rack 100. Thus, multiple rows of PSUs 110 can be installed in the power shelf 109 to provide the desired rack power.

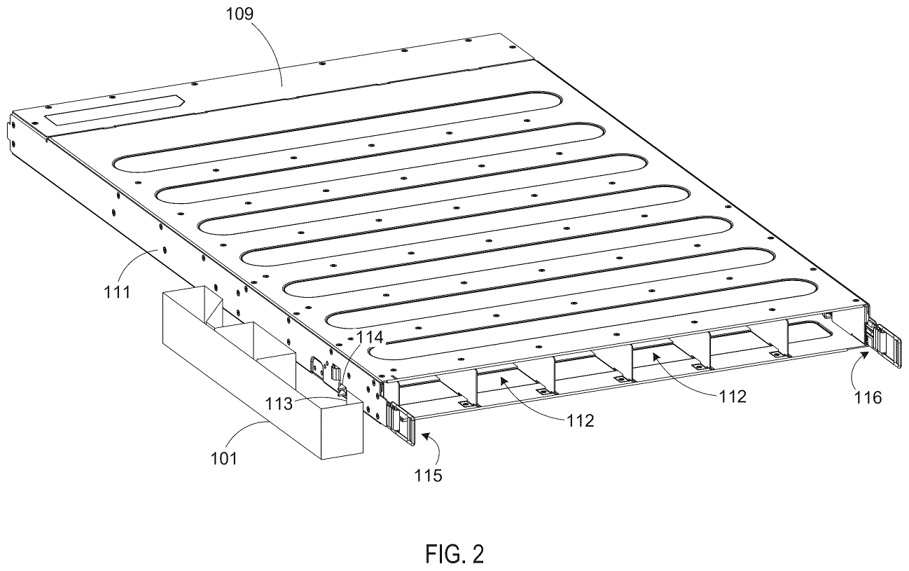

FIG. 2 illustrates the power shelf 109 of FIG. 1 latched within a portion of the equipment rack enclosure 101 of FIG. 1 according to one or more embodiments. The power shelf 109 includes a chassis 111 having a plurality of component openings 112 configured to have the PSUs 110 of FIG. 1 or other components installed thereinto.

The portion of the enclosure 101 shown in FIG. 2 includes a latching edge 113 against which one or more latch protrusions or teeth 114 of a latch assembly 115 may be engaged to secure the chassis 111 within the enclosure. When engaged, the latch teeth 114 engage the latching edge 113 to prevent the chassis 111 from being moved in a removal direction extending from a rear of the chassis 111 toward the front of the chassis 111. Thus, inadvertent movements or disengagements of the chassis 111 from the enclosure 101 due to external rack vibrations or from user handling can be eliminated. A second latch assembly 116 having latch protrusions (not shown in FIG. 2) can be used to further secure an opposite side of the chassis 111 to the enclosure 101. The latch assembly 116 represents a mirror image assembly to the latch assembly 115 described herein. Accordingly, the same features and benefits of the latch assembly 115 may be found in and implemented in the latch assembly 116 for use on the opposite side of the chassis 111.

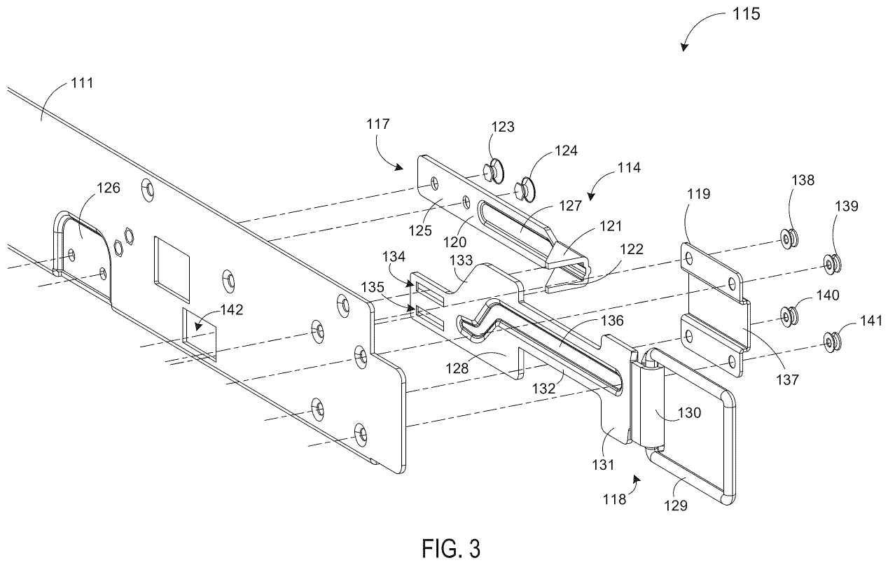

FIG. 3 illustrates an exploded view of the latch assembly 115 of FIG. 2 according to one or more embodiments. The latch assembly 115 includes an inner latch 117, a pull-out lever 118, and a bracket 119. The inner latch 117 includes a main portion 120 from which the latch protrusions 114 are bent at a proximal end of the main portion 120 to form two latch teeth 121, 122. Via a pair of fasteners 123, 124, a distal end of the inner latch 117 (e.g., a fixing portion 125) is coupled with the chassis 111. As shown, a depressed region or rib 126 in an outside surface of the chassis 111 is formed to extend a corresponding inner surface of the chassis 111 to create a standoff for the main portion 120 of the inner latch 117 such that space is created for the main portion 120 to overlap the pull-out lever 118. The main portion 120 of the inner latch 117 may include one or more ribs 127 to strengthen the inner latch 117 and/or to influence a bending or spring force of the main portion 120. The inner latch 117 is preferably formed from a single sheet of an appropriate metal such as steel.

The pull-out lever 118 includes a main portion 128 and a handle 129. At a proximal end of the main portion 128, a handle portion 130 is formed to couple with the handle 129 to facilitate interaction with the pull-out lever 118. A rounded portion of the main portion 128 is created to form the handle portion 130, and the handle 129 is pivotable with respect to the handle portion 130. Adjacent to the handle portion 130 is a forward portion 131 that, according to some embodiments, extends the handle portion 130 beyond a front of the chassis 111. A thinner bracket portion 132 is formed in the main portion 128 of the main portion 128 beyond the handle portion 130. At a distal end of the pull-out lever 118, a rear portion 133 is formed beyond the bracket portion 132 that includes a pair of latch openings 134, 135 configured to allow respective latch teeth 121, 122 to extend therein and therethrough. One or more ribs 136 may be formed in the main portion 128 to provide strengthening. The main portion 128 is preferably formed from a single sheet of an appropriate metal such as steel.

The bracket 119 includes a raised portion 137 configured to allow the bracket 119 to surround a portion of the bracket portion 132 of the pull-out lever 118 when secured to the chassis 111 via fasteners 138, 139, 140, 141. The raised portion 137 allows the pull-out lever 118 to move along a sliding axis and restricts rotational movement of the pull-out lever 118. A length of the bracket 119 is shorter than a length of the bracket portion 132 of the pull-out lever 118 to allow the pull-out lever 118 to allow the pull-out lever 118 to slide toward the front or to the rear of the chassis 111. The bracket 119 is preferably formed from a single sheet of an appropriate metal such as steel.

As described above, the fasteners 123, 124 secure a distal end of the inner latch 117 to the chassis 111. Accordingly, movement of the distal end of the inner latch 117 with respect to the chassis 111 is prevented. However, portions of the inner latch 117 forward of the fastener 124 are floating with respect to the chassis 111 and can bend away from or toward the chassis 111 as caused or allowed to do so by the pull-out lever 118. In this manner, greater or lesser amounts of the latch protrusions 114 can extend through a latch opening 142 in the chassis 111. When fully extended through the latch opening 142, a secure latched status of the chassis 111 can be established as illustrated in FIG. 2.

Also as described above, the fasteners 138-141 secure the bracket 119 to the chassis 111. The bracket 119 does not move relative to the chassis 111. However, the pull-out lever 118 that is positioned between the raised portion 137 of the bracket 119 and the chassis 111 can move in a sliding manner with respect to the chassis 111 toward the front or rear of the chassis 111. The pull-out lever 118 is not secured by any other means to the chassis 111.

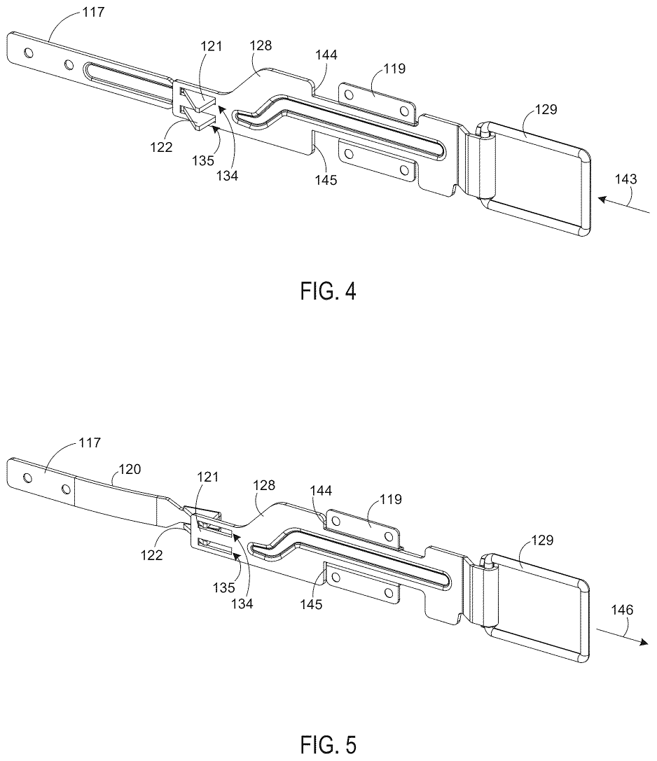

FIG. 4 illustrates an isometric view of the latch assembly 115 of FIG. 2 in a latching state according to one or more embodiments. As shown, the pull-out lever 118 (including the main portion 128 and handle 129) are positioned in a rearmost orientation as indicated by arrow 143. In this position, the latch teeth 121, 122 are fully extended through the latch openings 134, 135 of the main portion 128 of the pull-out lever 118. There is further little to no flexing or bending in the main portion 120 of the inner latch 117. When positioned in the latching state as shown, a top stopping edge 144 and a bottom stopping edge 145 of the rear portion 133 of the main portion 128 are farthest from the bracket 119.

FIG. 5 illustrates an isometric view of the latch assembly 115 of FIG. 2 in an unlatching state according to one or more embodiments. As indicated by arrow 146, the pull-out lever 118 is positioned in a foremost orientation or at a retraction limit. In this position, the top and bottom stopping edges 144, 145 are abutting the bracket 119 and prevent the pull-out lever 118 from being removed from engagement with the latch teeth 121, 122 of the inner latch 117. As shown, the main portion 120 is in a flexed or bent state such that a majority of the latch teeth 121, 122 is withdrawn from the latch opening 142 (see FIG. 3) in the chassis 111. A portion of the latch teeth 121, 122 may, however, still extend within the latch opening 142. However, it is preferable that the latch teeth 121, 122 do not extend all the way through the latch opening 142 such that engagement with any part of the latch teeth 121, 122 with the latching edge 113 of the enclosure 101 (see FIG. 1) is prevented. In this manner, the power shelf 109 may be removed from the enclosure 101 as desired.

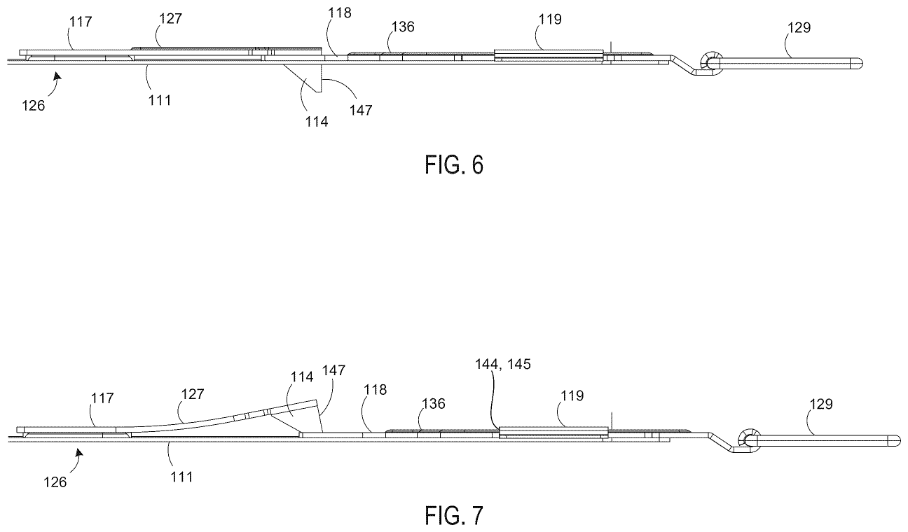

FIG. 6 illustrates a plan view of the latch assembly 115 of FIG. 4 in the latching state according to one or more embodiments. As shown, the inner latch 117 is in an unbent or relaxed state, and the latch protrusions 114 extend through the pull-out lever 118 and the chassis 111. In this manner, a forward edge 147 of the latch protrusions 114 provides a stop against the latching edge 113 of the enclosure 101 as illustrated in FIG. 2.

FIG. 7 illustrates a plan view of the latch assembly 115 of FIG. 5 in the unlatching state according to one or more embodiments. The pull-out lever 118 is in the fully extracted position as allowable by the bracket 119 and the top and bottom stopping edges 144, 145. As shown, the distal ends of the latch protrusions 114 do not extend beyond an outer surface of the chassis 111. As such, the forward edge 147 does not prevent removal of the power shelf 109 from the enclosure 101.

As shown in FIG. 6, when the pull-out lever 118 is in the latching state, the greatest amount of the latch protrusions 114 is inserted into the latch openings 134, 135. FIG. 7 shows that when the pull-out lever 118 is in the unlatching state, the least amount of the latch protrusions 114 is inserted into the latch openings 134, 135. Thus, as the pull-out lever 118 moves toward the latching state from the unlatching state, a greater amount of the latch protrusions 114 is inserted into the latch openings 134, 135 during each incremental movement. In contrast, as the pull-out lever 118 moves toward the unlatching state from the latching state, a lesser amount of the latch protrusions 114 is found within the latch openings 134, 135 during each incremental movement.

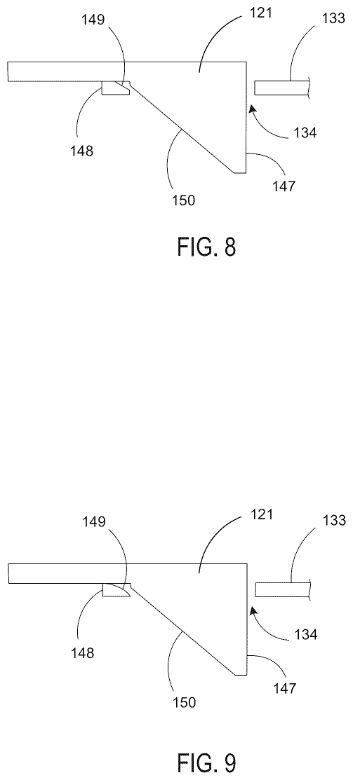

FIGS. 8 and 9 illustrate cutaway views of a portion of the latch assembly of FIG. 4 according to one or more alternative embodiments. A portion of the rear portion 133 of the main portion 128 of the pull-out lever 118 is illustrated about the latch opening 134. A distal end 148 of the rear portion 133 shows a contact point surface 149 of the latch opening 134 that is engageable with a ramp edge 150 of the latch tooth 121. As illustrated in FIG. 8, the distal end 148 and contact point surface 149 are in the shape of a flat wedge. As illustrated in FIG. 9, the distal end 148 and contact point surface 149 are in the shape of a rounded wedge. The flat and rounded wedge shapes reduce a pulling force required to move the pull-out lever 118 in the extension direction as shown by the arrow 146 of FIG. 5. In an example in which a length of the main portion 120 of the inner latch 117 is a fixed length, a latch pull force experienced in the presence of the flat wedge shape shown in FIG. 8 was measured to be 47.9N while the latch pull force experienced in the presence of the rounded wedge shape shown in FIG. 9 was measured to be 46.7N. The latch pull force may also be affected by the length of the main portion 120 of the inner latch 117. For example, a longer length reduces the latch pull force when compared with a shorter length. In addition, a choice of the material used to form the inner latch 117 may further affect the spring or bending force as well as the latch pull force required at the handle 129.

In addition to easing the force required to move the pull-out lever 118 toward the unlatching state, the contact point surface 149 and the ramp edge 150 also work together to help pull the pull-out lever 118 back toward the latching state shown in FIGS. 4, 8 and 9. That is, the spring force applied by the main portion 120 of the inner latch 117 causes the ramp edge 150 to pull the contact point surface 149 backwards as the latch tooth 121 is allowed to be forced farther into the latch opening 134 by the spring force. In one embodiment, the amount of spring force together with the shapes and angles of the distal end 148 and the ramp edge 150 may be sufficient to pull the pull-out lever 118 back into the latching position in the absence of any counter force applied by a user via the handle 129.

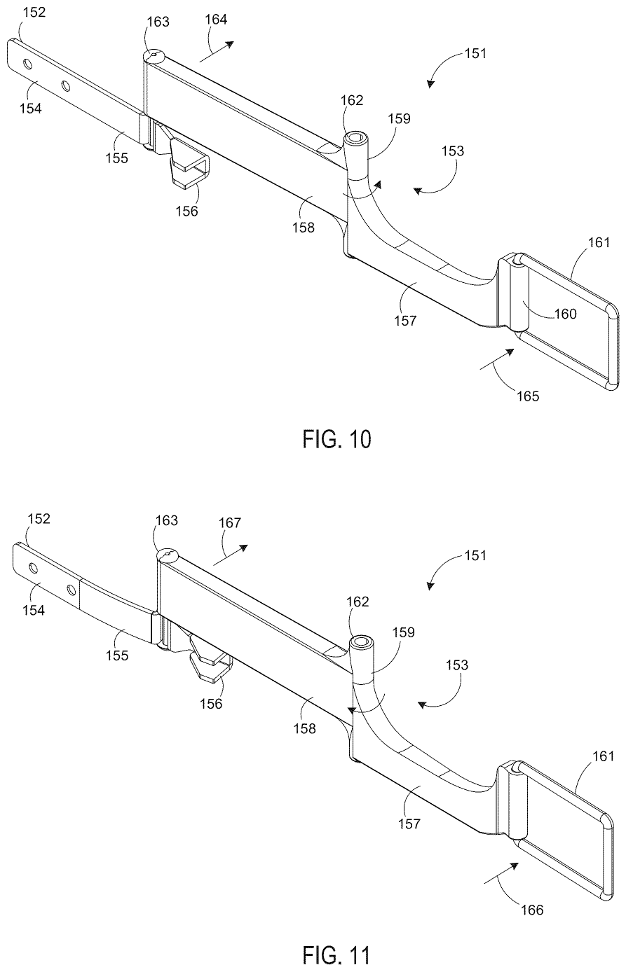

FIG. 10 illustrates an isometric view of an alternative latch assembly 151 in a latching state according to one or more embodiments. The latch assembly 151 includes an inner latch 152 and a rotating lever 153. The inner latch 152 includes a fixing portion 154 and a main portion 155 having latch teeth 156 formed therein. As with the inner latch 117 described above, the fixing portion 154 is coupled with the chassis 111 via fasteners such as fasteners 123, 124 (e.g., see FIG. 3) while the main portion 155 is bendable and movable away from and toward the chassis 111.

The rotating lever 153 includes a proximal member 157 and a distal member 158 joined at a central portion 159. The proximal member 157 includes a handle portion 160 formed therein for coupling with a handle 161.

A center pin 162 couples the rotating lever 153 with the chassis 111 (not shown) and allows the rotating lever 153 to rotate with respect to the chassis 111. A joining pin 163 couples the distal member 158 of the rotating lever 153 with the main portion 155.

The position of the latch assembly 151 in FIG. 10 is in a latching position or state. Whether the spring force of the inner latch 152 pulls the joining pin 163 in the direction indicated by the arrow 164 or whether an external force moves the handle 161 in the direction indicated by the arrow 165, the effect causes the latch teeth 156 to fully extend in a similar manner as described with respect to FIG. 4.

As illustrated in FIG. 11, in response to an external force being applied to the handle 161 in a direction as indicated by the arrow 166, the distal member 158 rotates to move the joining pin 163 in the direction as indicated by the arrow 167, which disengages the latch teeth 156 from the chassis 111 and causes the latch teeth 156 to be fully retracted in a similar manner as described with respect to FIG. 5.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the present disclosure. Additionally, while various embodiments of the present disclosure have been described, it is to be understood that aspects of the present disclosure may include only some of the described embodiments. Accordingly, the invention is not to be seen as limited by the foregoing description but is only limited by the scope of the appended claims.

1. A latch assembly comprising:
a latch having a first protrusion extending from a first end of the latch;
a lever having a first portion adjacent to a first protrusion opening; and
a bracket configured to engage the lever to confine a movement of the lever along a sliding axis;
wherein the first protrusion opening is configured to allow a portion of the first protrusion to extend therethrough;
wherein a sliding movement of the lever along the sliding axis in a first direction causes a greater amount of the first protrusion to be within the first protrusion opening; and
wherein a sliding movement of the lever along the sliding axis in a second direction causes a lesser amount of the first protrusion to be within the first protrusion opening.

2. The latch assembly of claim 1, wherein the latch has a second protrusion formed in the proximal end thereof;
wherein the lever has a second protrusion opening formed in the distal end thereof; and
wherein the second protrusion opening is configured to allow a portion of the second protrusion to extend therethrough.

3. The latch assembly of claim 1, wherein the latch comprises:
a fixing portion configured to be fixedly coupled with a chassis; and
a main portion comprising the proximal end;
wherein the main portion is bendable with respect to the fixing portion.

4. The latch assembly of claim 1, wherein the lever comprises:
a proximal end; and
a bracket portion extending between the distal end and the proximal end;
wherein the bracket portion is configured to slidingly engage the bracket.

5. The latch assembly of claim 4, wherein the bracket comprises a raised portion configured to engage the bracket portion.

6. The latch assembly of claim 5, wherein the bracket is configured to restrict movement of the lever to a sliding movement.

7. The latch assembly of claim 1, wherein a first wall surface forming a portion of the first protrusion opening is shaped as a flat wedge.

8. The latch assembly of claim 1, wherein a first wall surface forming a portion of the first protrusion opening is shaped as a rounded wedge.

9. A latching component comprising:
a chassis comprising a chassis wall;
a latch member having a proximal portion thereof affixed to the chassis wall and comprising:
a distal end; and
a first latch tooth extending from the distal end;
a bracket fixedly attached to the chassis wall; and
a lever comprising:
a distal end positioned between the distal end of the latch member and the chassis wall; and
a bracket portion positioned between the bracket and the chassis wall;
wherein the distal end of the lever has a first portion adjacent to a first latch tooth opening;
wherein the lever is configured to slide in a first direction to allow a greater portion of the first latch tooth to be positioned within the first latch tooth opening; and
wherein the lever is configured to slide in a second direction opposite the first direction to allow a lesser portion of the first latch tooth to be positioned within the first latch tooth opening.

10. The latching component of claim 9, wherein the chassis wall has a rib formed therein; and
wherein the proximal portion of the latch member is affixed to the rib.

11. The latching component of claim 9, wherein the latch member further comprises a second latch tooth formed at the distal end;
wherein the distal end of the lever further has a second latch tooth opening formed therein;
wherein the lever is configured to slide in the first direction to allow a greater portion of the second latch tooth to be positioned within the second latch tooth opening; and
wherein the lever is configured to slide in the second direction to allow a lesser portion of the second latch tooth to be positioned within the second latch tooth opening.

12. The latching component of claim 9, wherein the chassis wall has a latch opening formed therein;
wherein, in response to the lever being in a latching state, a first amount of the first latch tooth is positioned within the latch opening; and
wherein, in response to the lever being in an unlatching state, no amount of the first latch tooth is positioned within the latch opening.

13. The latching component of claim 9, wherein the lever further comprises:
a proximal end extending from the bracket portion; and
a handle portion formed in the proximal end.

14. The latching component of claim 9, wherein the distal end of the lever comprises:
a top stopping edge; and
a bottom stopping edge;
wherein the top and bottom edges are configured to abut the bracket to restrict movement of the lever beyond a retraction limit in the second direction.

15. The latching component of claim 9, wherein a first wall surface forming a portion of the first latch tooth opening is shaped as a flat wedge.

16. The latching component of claim 9, wherein a first wall surface forming a portion of the first latch tooth opening is shaped as a rounded wedge.

17. A method comprising:
forming a pair of latching teeth in a distal end of a latch;
attaching a proximal end of the latch to a chassis wall;
forming a pair of latch teeth openings in a distal end of a lever;
coupling the lever with the distal end of the latch; and
attaching a bracket to the chassis wall and about a portion of the lever;
wherein the bracket is configured to allow sliding movement of the lever with respect to the latch;
wherein, in response to sliding movement of the lever in a first direction, the pair of latching teeth is caused to be moved in an insertion direction within the latch teeth openings; and
wherein, in response to sliding movement of the lever in a second direction, the pair of latching teeth is caused to be moved in a withdrawal direction within the latch teeth openings.

18. The method of claim 17 further comprising:
forming a rib in the distal end of the latch; and
forming a rib in the distal end of the lever.

19. The method of claim 17 further comprising shaping first wall surfaces of the pair of latch teeth openings according to one of a flat wedge shape and a rounded edge shape.

20. The method of claim 17 further comprising forming a latch opening in the chassis wall, the latch opening configured to allow a portion of the pair of latching teeth to extend therethrough.
